(19) United States
(12) Patent Application Publication
(10) Pub. No.: US 2026/0271536 A1
(43) Pub. Date: Sep. 10, 2026

(54) DISPLAY PANEL AND DISPLAY APPARATUS

(71) Applicant: Hefei Visionox Technology Co., Ltd., Hefei (CN)

(72) Inventor: Zhiwei ZHOU, Hefei (CN)

(73) Assignee: Hefei Visionox Technology Co., Ltd., Hefei (CN)

(21) Appl. No.: 19/417,224

(22) Filed: Dec. 11, 2025

(30) Foreign Application Priority Data
Mar. 6, 2025 (CN) 202510266140.1

(51) Int. Cl. H10K 59/122

(52) U.S. Cl. CPC H10K 59/122

(57) ABSTRACT

Embodiments of the present application provide a display panel and a display apparatus. The display panel includes: an isolation structure. The isolation structure includes a first sublayer and a second sublayer, the first sublayer having a first surface on a side that faces the second sublayer. The isolation structure includes a first isolation sub-structure and a second isolation sub-structure, where an area of contact between the second isolation sub-structure and the second electrode is less than an area of contact between the first isolation sub-structure and the second electrode, and at least part of an orthographic projection of the second sublayer of the second isolation sub-structure on the substrate is spaced apart from another part of the edge of the orthographic projection of the first electrode on the substrate. Thus, the process performance of the display panel is improved.

### CROSS-REFERENCE TO RELATED APPLICATIONS

The present application claims priority to the Chinese Patent Application No. 202510266140.1, filed on Mar. 6, 2025, and the entire contents of the aforementioned application are hereby incorporated by reference in its entirety.

### FIELD

The present application relates to the field of display devices, and particularly to a display panel and a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN 118251982 A, CN 115666161 A, CN 116648095 A, CN 117062489 A, CN 118678742 A, CN 118785761 A, CN 115224220 A, CN 118678729 A, CN 118660529 A, and CN 118660589 A.

However, the process performance of current display products needs to be improved.

### SUMMARY

Embodiments of the present application provide a display panel and a display apparatus, which are intended to improve the process performance of the display panel.

An embodiment of a first aspect of the present application provides a display panel. The display panel includes: a substrate, a first electrode layer, an isolation structure, and a second electrode layer, where the first electrode layer is disposed on a side of the substrate, and the first electrode layer includes a plurality of first electrodes spaced apart from each other; the isolation structure is disposed on a side of the substrate, and the isolation structure encloses a plurality of isolation openings, an orthographic projection of the isolation opening on the substrate at least partially overlapping an orthographic projection of the first electrode on the substrate, where the isolation structure includes a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer; and the second electrode layer is disposed on a side of the first electrode layer that faces away from the substrate, and the second electrode layer includes a plurality of second electrodes located in the isolation openings, where the isolation structure enclosing the same isolation opening includes a first isolation sub-structure and a second isolation sub-structure, where the first isolation sub-structure is disposed in contact with the second electrode, and an orthographic projection of the first surface of the first isolation sub-structure on the substrate overlaps one part of an edge of the orthographic projection of the first electrode on the substrate; and an area of contact between the second isolation sub-structure and the second electrode is less than an area of contact between the first isolation sub-structure and the second electrode, and at least part of an orthographic projection of the second sublayer of the second isolation sub-structure on the substrate is spaced apart from another part of the edge of the orthographic projection of the first electrode on the substrate.

In an embodiment according to the present application, the orthographic projection of the first electrode on the substrate includes a first edge extending in a first direction and a second edge extending in a second direction, where an extension length of the first edge in the first direction is greater than an extension length of the second edge in the second direction, the first edge at least partially overlaps the orthographic projection of the first surface of the first isolation sub-structure on the substrate, and at least part of the second edge is spaced apart from the orthographic projection of the second sublayer of the second isolation sub-structure on the substrate, the first direction intersecting the second direction.

In an embodiment according to the present application, the second electrode includes a first side edge extending in a first direction and a second side edge extending in a second direction, where an extension length of the first side edge in the first direction is greater than an extension length of the second side edge in the second direction, the first side edge is connected to the first isolation sub-structure, and an area of contact between the second side edge and the second isolation sub-structure is less than an area of contact between the first isolation sub-structure and the first side edge.

In an embodiment according to the present application, at least part of the second side edge is spaced apart from the second isolation sub-structure.

In an embodiment according to the present application, two second edges are disposed opposite to each other in the first direction, with one of the two second edges being a first short edge, and the other of the two second edges being a second short edge; and the substrate includes a base, a drive circuit layer, and an insulating layer that are disposed sequentially, the first electrode and the isolation structure being disposed on a side of the insulating layer that faces away from the base, and the insulating layer being provided with a first via through which the first electrode is electrically connected to the drive circuit layer, where an orthographic projection of the first via on the base is on a side where the second short edge is located, the first short edge is spaced apart from an orthographic projection of the second sublayer of the second isolation sub-structure on the base, and the second short edge at least partially overlaps an orthographic projection of the first surface of the second isolation sub-structure on the base.

In an embodiment according to the present application, two second side edges are disposed opposite to each other in the first direction, and the two second side edges include a first sub-side edge away from a side where the first via is located and a second sub-side edge close to the side where the first via is located, where the first sub-side edge is spaced apart from the isolation structure, and the second sub-side edge is connected to the isolation structure.

In an embodiment according to the present application, in a direction perpendicular to a thickness direction of the display panel, a minimum spacing between the second short edge and the orthographic projection of the second sublayer on the substrate is greater than or equal to 0.8 micrometer, where the second short edge and the second sublayer are located in the same isolation opening.

In an embodiment according to the present application, the first isolation sub-structure extends in the first direction, the second isolation sub-structure extends in the second direction, and two oppositely disposed first isolation sub-structures and two oppositely disposed second isolation sub-structures enclose the isolation opening, where an extension length of the first isolation sub-structure in the first direction is greater than or equal to an extension length of the second isolation sub-structure in the second direction; the first electrode includes two second surfaces disposed opposite to each other in a thickness direction of the display panel and a sidewall connected between the two second surfaces, the sidewall including a first sidewall on a side of the first electrode that faces the first isolation sub-structure and a second sidewall on a side of the first electrode that faces the second isolation sub-structure, where an orthographic projection of the first sidewall on the substrate forms the first edge, and the second sidewall includes a first sub-portion and a second sub-portion that are disposed opposite to each other in the first direction, an orthographic projection of the first sub-portion on the substrate forming the first short edge, and an orthographic projection of the second sub-portion on the substrate forming the second short edge; and the display panel further includes a light-emitting layer disposed on a side of the first electrode layer that faces away from the substrate, the light-emitting layer including light-emitting units disposed in the isolation openings, where the second electrode layer is disposed on a side of the light-emitting layer that faces away from the substrate, two second isolation sub-structures each include a first sub-segment close to the first sub-portion and a second sub-segment close to the second sub-portion, the second electrode being electrically connected to the second sub-segment, and the second electrode being spaced apart from the first sub-segment.

In an embodiment according to the present application, an orthographic projection of the first surface of the second sub-segment on the substrate at least partially overlaps the orthographic projection of the second sub-portion on the substrate.

In an embodiment according to the present application, the second electrode is electrically connected to the first isolation sub-structure and the second sub-segment.

In an embodiment according to the present application, the isolation structure further includes a third sublayer disposed on a side of the first sublayer that faces the substrate.

In an embodiment according to the present application, an orthographic projection, on the substrate, of a side of the third sublayer of the first sub-segment that faces the first sub-portion is within an orthographic projection of the first surface of the first sub-segment on the substrate, and the third sublayer of the first sub-segment is insulated and spaced apart from the second electrode.

In an embodiment according to the present application, the third sublayer of the second sub-segment protrudes toward the isolation opening from the first sublayer, and is electrically connected to the second electrode.

In an embodiment according to the present application, the third sublayer of the first isolation sub-structure protrudes toward the isolation opening from the first sublayer, and is connected to the second electrode.

In an embodiment according to the present application, the second sublayer includes a third sidewall on a side that faces the isolation opening, and in a direction perpendicular to a thickness direction of the display panel, a minimum spacing between the second sub-portion and the third sidewall is greater than a minimum spacing between the first sidewall and the third sidewall.

In an embodiment according to the present application, in the direction perpendicular to the thickness direction of the display panel, a minimum spacing between the third sidewall and the first sidewall that are located in the same isolation opening is greater than or equal to 0.8 micrometer.

In an embodiment according to the present application, in the direction perpendicular to the thickness direction of the display panel, a minimum spacing between the first sub-portion and the third sidewall of the first sub-segment is greater than or equal to 0.8 micrometer.

In an embodiment according to the present application, the isolation structure includes a first transition segment connected between the first isolation sub-structure and the second isolation sub-structure, and the first electrode includes a second transition segment connected between the first sidewall and the second sidewall, where at least part of an orthographic projection of the second transition segment on the substrate is within an orthographic projection of the first surface of the first transition segment on the substrate.

In an embodiment according to the present application, a radius of curvature of the first transition segment is less than a radius of curvature of the second transition segment.

In an embodiment according to the present application, a size of the second isolation sub-structure in the first direction is less than a size of the first isolation sub-structure in the second direction.

In an embodiment according to the present application, the display panel further includes a pixel definition layer, the pixel definition layer including a pixel defining portion and a pixel opening enclosed by the pixel defining portion, where the light-emitting unit is located in the pixel opening, and the isolation structure is disposed on a side of the pixel defining portion that faces away from the substrate.

In an embodiment of the present application, a size, in the first direction, of the pixel defining portion on a side of the second isolation sub-structure that faces the substrate is less than a size, in the first direction, of the pixel defining portion on a side of the first isolation sub-structure that faces the substrate.

An embodiment of the first aspect of the present application further provides a display panel. The display panel includes: a substrate; a first electrode layer disposed on a side of the substrate, the first electrode layer including a plurality of first electrodes spaced apart from each other; an isolation structure disposed on a side of the substrate, the isolation structure enclosing a plurality of isolation openings, an orthographic projection of the isolation opening on the substrate at least partially overlapping an orthographic projection of the first electrode on the substrate, where the isolation structure includes a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer; and the orthographic projection of the first electrode on the substrate includes a first edge extending in a first direction and a second edge extending in a second direction, where an extension length of the first edge in the first direction is greater than an extension length of the second edge in the second direction, the first direction intersecting the second direction; and a second electrode layer disposed on a side of the first electrode layer that faces away from the substrate, the second electrode layer including a plurality of second electrodes located in the isolation openings, where the isolation structure enclosing the same isolation opening includes a first isolation sub-structure and a second isolation sub-structure, where the first isolation sub-structure is disposed in contact with the second electrode, and an orthographic projection of the first surface of the first isolation sub-structure on the substrate overlaps the first edge; and at least part of an orthographic projection of the second isolation sub-structure on the substrate is spaced apart from the second edge.

In an embodiment according to the present application, the second electrode includes a first side edge extending in the first direction and a second side edge extending in the second direction, the first side edge being connected to the first isolation sub-structure, and at least part of the second side edge being spaced apart from the second isolation sub-structure.

An embodiment of the first aspect of the present application further provides a display panel. The display panel includes: a substrate; a first electrode layer disposed on a side of the substrate, the first electrode layer including a plurality of first electrodes spaced apart from each other; and an isolation structure disposed on a side of the substrate, the isolation structure enclosing isolation openings, an orthographic projection of the isolation opening on the substrate at least partially overlapping an orthographic projection of the first electrode on the substrate, where the isolation structure includes a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer; the isolation structure includes a first isolation sub-structure, a second isolation sub-structure, and a first transition segment connected between the first isolation sub-structure and the second isolation sub-structure; the first electrode includes two second surfaces disposed opposite to each other in a thickness direction of the display panel and a sidewall connected between the two second surfaces, the sidewall including a first sidewall on a side of the first electrode that faces the first isolation sub-structure and a second sidewall on a side of the first electrode that faces the second isolation sub-structure; and the first electrode further includes a second transition segment connected between the first sidewall and the second sidewall, where at least part of an orthographic projection of the second transition segment on the substrate is within an orthographic projection of the first surface of the first transition segment on the substrate.

In an embodiment according to the present application, a radius of curvature of the first transition segment is less than a radius of curvature of the second transition segment.

An embodiment of a second aspect of the present application further provides a display apparatus, including a display panel according to any one of the above embodiments of the first aspect.

In an embodiment of the present application, an orthographic projection of a first surface of a first isolation sub-structure on a substrate overlaps one part of an edge of an orthographic projection of a first electrode on the substrate, which reduces the impact of part of a sidewall of the first electrode on the surface flatness of part of a second sublayer of the first isolation sub-structure that protrudes from the first surface. At least part of an orthographic projection of the second sublayer of a second isolation sub-structure on the substrate is spaced apart from another part of the edge of the orthographic projection of the first electrode on the substrate, which reduces the impact of the other part of the sidewall of the first electrode on the surface flatness of part of the second sublayer of the second isolation sub-structure that protrudes from the first surface. The orthographic projection of the first surface of the first isolation sub-structure on the substrate overlaps one part of the edge of the orthographic projection of the first electrode on the substrate, and the first isolation sub-structure is disposed in contact with a second electrode, which reduces the impact of a sidewall on a side of the first electrode that is close to the first isolation sub-structure on the uniformity of the film layer of part of the second electrode configured to be electrically connected to the first isolation sub-structure. The at least part of the orthographic projection of the second sublayer of the second isolation sub-structure on the substrate is spaced apart from another part of the edge of the orthographic projection of the first electrode on the substrate, an area of contact between the second isolation sub-structure and the second electrode is less than an area of contact between the first isolation sub-structure and the second electrode, which can reduce the parasitic capacitance generated between the first electrode and the second isolation sub-structure. A smaller area of contact between the second electrode and the second isolation sub-structure enables the uniformity of the film layer of part of the second electrode electrically connected to the isolation structure to be less affected by the first electrode, thereby improving the process performance of the display panel.

### BRIEF DESCRIPTION OF THE DRAWINGS

By reading the following detailed description of non-limiting embodiments made with reference to the drawings, the embodiments of the present application will become more apparent, in which the same or similar features are denoted by the same or similar reference signs.

FIG. 1 is a schematic structural diagram of a display panel according to an embodiment of the present application;

FIG. 2 is a schematic partial structural diagram of the display panel of FIG. 1;

FIG. 3 is a cross-sectional view taken along line AA in FIG. 1;

FIG. 4 is a schematic structural diagram of another display panel according to an embodiment of the present application; and

FIG. 5 is a schematic partial structural diagram of still another display panel according to an embodiment of the present application.

List of reference signs: 100. substrate; 110. base; 120. drive circuit layer; 130. insulating layer; 131. first via; 200. first electrode; 201. edge; 202. second surface; 210. first edge; 220. second edge; 221. first short edge; 222. second short edge; 230. first sidewall; 240. second sidewall; 241. first sub-portion; 242. second sub-portion; 250. second transition segment; 300. isolation structure; 301. first sublayer; 302. second sublayer; 303. third sublayer; 304. isolation opening; 305. first surface; 306. third sidewall; 310. first isolation sub-structure; 320. second isolation sub-structure; 321. first sub-segment; 322. second sub-segment; 330. first transition segment; 400. light-emitting unit; 500. second electrode; 510. first side edge; 520. second side edge; 521. first sub-side edge; 522. second sub-side edge; 600. pixel defining portion; 610. pixel opening; X. first direction; Y. second direction; and Z. thickness direction.

### DETAILED DESCRIPTION OF THE EMBODIMENTS

The features and exemplary embodiments of the present application in various aspects are described in detail below. In the following detailed description, many specific details are set forth to comprehensively understand the present application. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the sizes of part of the structure may be enlarged. In addition, the features, structures, or characteristics described below may be combined, in any suitable manner, in one or more embodiments.

In the description of the present application, it should be noted that "a plurality of" means two or more, unless otherwise specified. The orientation or position relationship indicated by the terms "upper", "lower", "left", "right", "inner", "outer", etc. is merely for the convenience of describing the present application and simplifying the description, rather than indicating or implying that a device or element referred to must have a particular orientation or be constructed and operated in a particular orientation, and therefore should not be construed as limiting the present application. Moreover, the terms such as "first" and "second" are merely used for the illustrative purpose, and should not be construed as indicating or implying relative importance.

The orientation terms used in the following description all indicate directions shown in the accompanying drawings, and do not limit the specific structure of the embodiment of the present application. In the description of the present application, it should also be noted that unless otherwise explicitly specified and defined, the terms "mounting" and "connection" should be understood in a broad sense, for example, they may be a fixed connection, a detachable connection, or an integrated connection, and may be a direct connection, or an indirect connection. The specific meanings of the terms mentioned above in the present application may be construed according to specific circumstances.

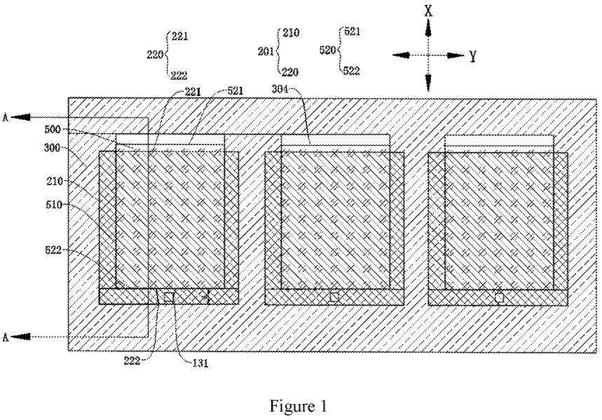

As shown in FIGS. 1 to 3, a display panel according to an embodiment of a first aspect of the present application includes: a substrate 100, a first electrode layer, an isolation structure 300, and a second electrode layer. The first electrode layer is disposed on a side of the substrate 100, and the first electrode layer includes a plurality of first electrodes 200 spaced apart from each other. The isolation structure 300 is disposed on a side of the substrate 100, and the isolation structure 300 encloses a plurality of isolation openings 304, an orthographic projection of the isolation opening 304 on the substrate 100 at least partially overlapping an orthographic projection of the first electrode 200 on the substrate 100. The isolation structure 300 includes a first sublayer 301 and a second sublayer 302 that are stacked in a direction away from the substrate 100, an orthographic projection of the first sublayer 301 on the substrate 100 being within an orthographic projection of the second sublayer 302 on the substrate 100, and the first sublayer 301 having a first surface 305 on a side that faces the second sublayer 302. The second electrode layer is disposed on a side of the first electrode layer that faces away from the substrate 100, and the second electrode layer includes a plurality of second electrodes 500 located in the isolation openings 304, where the isolation structure 300 enclosing the same isolation opening 304 includes a first isolation sub-structure 310 and a second isolation sub-structure 320, where the first isolation sub-structure 310 is disposed in contact with the second electrode 500, and an orthographic projection of the first surface 305 of the first isolation sub-structure 310 on the substrate 100 overlaps one part of an edge 201 of the orthographic projection of the first electrode 200 on the substrate 100; and an area of contact between the second isolation sub-structure 320 and the second electrode 500 is less than an area of contact between the first isolation sub-structure 310 and the second electrode 500, and at least part of an orthographic projection of the second sublayer 302 of the second isolation sub-structure 320 on the substrate 100 is spaced apart from another part of the edge 201 of the orthographic projection of the first electrode 200 on the substrate 100.

In this embodiment, the first electrode layer and the isolation structure 300 are disposed on a side of the substrate 100, the isolation structure 300 encloses the isolation opening 304, the orthographic projection of the isolation opening 304 on the substrate 100 at least partially overlaps the orthographic projection of the first electrode 200 on the substrate 100, and the first electrode 200 is exposed from the isolation opening 304. The isolation structure 300 includes the first sublayer 301 and the second sublayer 302 that are stacked in the direction away from the substrate 100, and the orthographic projection of the first sublayer 301 on the substrate 100 is within the orthographic projection of the second sublayer 302 on the substrate 100. When a light-emitting layer is prepared, the material of the light-emitting layer has a large drop at a side edge of the isolation structure 300 and breaks at the side edge of the isolation structure 300, thereby forming a light-emitting unit 400 located in the isolation opening 304. This eliminates the need for a precision mask, reducing the development and use of the precision mask and lowering the preparation cost. The first sublayer 301 has the first surface 305 on the side that faces the second sublayer 302, and part on a side of the second sublayer 302 that protrudes toward the isolation opening 304 from the first surface 305 is configured to separate the material of the light-emitting layer. The first electrode 200 is insulated from the isolation structure 300, and the orthographic projection of the first surface 305 of the first isolation sub-structure 310 on the substrate 100 overlaps one part of the edge 201 of the orthographic projection of the first electrode 200 on the substrate 100, reducing the impact of one part of a sidewall of the first electrode 200 on the surface flatness of part of the second sublayer 302 of the first isolation sub-structure 310 that protrudes from the first surface 305. The at least part of the orthographic projection of the second sublayer 302 of the second isolation sub-structure 320 on the substrate 100 is spaced apart from another part of the edge 201 of the orthographic projection of the first electrode 200 on the substrate 100, which reduces the impact of another part of the sidewall of the first electrode 200 on the surface flatness of part of the second sublayer 302 of the second isolation sub-structure that protrudes from the first surface 305. A better surface flatness of the part of the second sublayer 302 that protrudes from the first surface 305 can improve the separation effect on the material of the light-emitting layer. The second electrode layer includes the second electrodes 500 located in the isolation openings 304. One of the first electrode 200 and the second electrode 500 serves as an anode of the light-emitting unit 400, and the other serves as a cathode of the light-emitting unit 400. The second electrodes 500 spaced apart from each other are electrically connected to each other through the isolation structure 300 to form a continuous electrode, thereby ensuring normal light emission of the light-emitting unit 400. The first electrode 200 and the second electrode 500 are stacked. The second electrode 500 is formed on a side of the first electrode 200 that faces away from the substrate 100, and a sidewall in a peripheral direction of the first electrode 200 may have an impact on the uniformity of the film layer of the second electrode 500. The orthographic projection of the first surface 305 of the first isolation sub-structure 310 on the substrate 100 overlaps one part of the edge 201 of the orthographic projection of the first electrode 200 on the substrate 100, and the first isolation sub-structure 310 is disposed in contact with the second electrode 500, reducing the impact of a sidewall on a side of the first electrode 200 that is close to the first isolation sub-structure 310 on the uniformity of the film layer of part of the second electrode 500 configured to be electrically connected to the first isolation sub-structure 310. The at least part of the orthographic projection of the second sublayer 302 of the second isolation sub-structure 320 on the substrate 100 is spaced apart from another part of the edge 201 of the orthographic projection of the first electrode 200 on the substrate 100, and the area of contact between the second isolation sub-structure 320 and the second electrode 500 is less than the area of contact between the first isolation sub-structure 310 and the second electrode 500, which can reduce the parasitic capacitance generated between the first electrode 200 and the second isolation sub-structure 320. A smaller area of contact between the second electrode 500 and the second isolation sub-structure 320 enables the uniformity of the film layer of part of the second electrode 500 electrically connected to the isolation structure 300 to be less affected by the first electrode 200, thereby improving the process performance of the display panel.

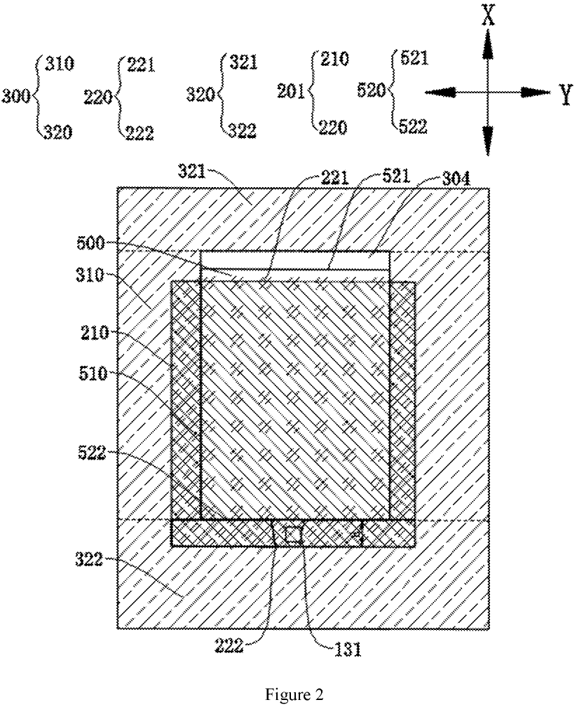

In one embodiment, as shown in FIG. 2, the area of contact between the second isolation sub-structure 320 and the second electrode 500 may be less than the area of contact between the first isolation sub-structure 310 and the second electrode 500, or at least part of the second isolation sub-structure 320 is spaced apart from the second electrode 500, and the area of contact between the second isolation sub-structure 320 and the second electrode 500 is less than the area of contact between the first isolation sub-structure 310 and the second electrode 500.

As shown in FIGS. 1 to 3, in some embodiments, the orthographic projection of the first electrode 200 on the substrate 100 includes a first edge 210 extending in a first direction X and a second edge 220 extending in a second direction Y. An extension length of the first edge 210 in the first direction X is greater than an extension length of the second edge 220 in the second direction Y. The first edge 210 at least partially overlaps the orthographic projection of the first surface 305 of the first isolation sub-structure 310 on the substrate 100, and at least part of the second edge 220 is spaced apart from the orthographic projection of the second sublayer 302 of the second isolation sub-structure 320 on the substrate 100. The first direction X intersects the second direction Y.

In these embodiments, two first edges 210 and two second edges 220 are alternately connected to each other. The two first edges 210 are disposed opposite to each other in the second direction Y, and the two second edges 220 are disposed opposite to each other in the first direction X. The at least part of the second edge 220 is spaced apart from the orthographic projection of the second sublayer 302 of the second isolation sub-structure 320 on the substrate 100, which reduces the parasitic capacitance generated due to part on a side of the first electrode 200 that faces the second edge 220 directly facing the isolation structure 300.

In one embodiment, the first direction X, the second direction Y, and the thickness direction Z of the display panel are perpendicular to each other.

In one embodiment, as shown in FIGS. 1 and 2, the second electrode 500 includes a first side edge 510 extending in the first direction X and a second side edge 520 extending in the second direction Y. An extension length of the first side edge 510 in the first direction X is greater than an extension length of the second side edge 520 in the second direction Y, and the first side edge 510 is connected to the first isolation sub-structure 310. An area of contact between the second side edge 520 and the second isolation sub-structure 320 is less than an area of contact between the first isolation sub-structure 310 and the first side edge 510, which facilitates an increase in the area of contact between the second electrode 500 and the isolation structure 300 and a reduction in the resistance of the second electrode 500.

In one embodiment, as shown in FIGS. 1 to 3, at least part of the second side edge 520 is spaced apart from the second isolation sub-structure 320, which enables the uniformity of the film layer of the part of the second electrode 500 electrically connected to the isolation structure 300 to be less affected by the first electrode 200.

As shown in FIGS. 1 to 3, in some embodiments, two second edges 220 are disposed opposite to each other in the first direction X. One of the two second edges 220 is a first short edge 221, and the other of the two second edges 220 is a second short edge 222. The substrate 100 includes a base 110, a drive circuit layer 120, and an insulating layer 130 that are disposed sequentially. The first electrode 200 and the isolation structure 300 are disposed on a side of the insulating layer 130 that faces away from the base 110, and the insulating layer 130 is provided with a first via 131. The first electrode 200 is electrically connected to the drive circuit layer 120 through the first via 131. An orthographic projection of the first via 131 on the base 110 is on a side where the second short edge 222 is located. The first short edge 221 is spaced apart from an orthographic projection of the second sublayer 302 of the second isolation sub-structure 320 on the base 110, and the second short edge 222 at least partially overlaps an orthographic projection of the first surface 305 of the second isolation sub-structure 320 on the base 110.

In these embodiments, the first electrode 200 is electrically connected to the drive circuit layer 120 through the first via 131, the drive circuit layer 120 is configured to transmit an electrical signal to the first electrode 200, and the first electrode 200 is one of an anode or a cathode. The orthographic projection of the first via 131 on the base 110 is on the side where the second short edge 222 is located, and the first electrode 200 is electrically connected to the drive circuit layer 120 through the first via 131. The orthographic projection of the first via 131 on the base 110 is on the side where the second short edge 222 is located, and the first electrode 200 is connected to the first via 131 through the part close to the second short edge 222. The second short edge 222 at least partially overlaps the orthographic projection of the first surface 305 of the second isolation sub-structure 320 on the base 110 to be electrically connected to the drive circuit layer 120 through the first via 131, and the second short edge 222 at least partially overlaps an orthographic projection of the first surface 305 of the second isolation sub-structure 320 on the substrate 100, which can reduce the impact of a sidewall of the first electrode 200 that faces the second short edge 222 on the surface flatness of the part of the second sublayer 302 that protrudes from the first surface 305. The first short edge 221 is spaced apart from an orthographic projection of the isolation structure 300 on the base 110, which reduces the area of direct facing between the first electrode 200 and the isolation structure 300 and thus the parasitic capacitance between the first electrode 200 and the isolation structure 300.

In one embodiment, two second side edges 520 are disposed opposite to each other in the first direction X. The two second side edges 520 each include a first sub-side edge 521 away from a side where the first via 131 is located and a second sub-side edge 522 close to the side where the first via 131 is located. The first sub-side edge 521 is spaced apart from the isolation structure 300, and the second sub-side edge 522 is connected to the isolation structure 300. The second short edge 222 at least partially overlaps the orthographic projection of the isolation structure 300 on the base 110, which reduces the impact of a sidewall on a side of the first electrode 200 that faces the second short edge 222 on the uniformity of the film layer of the second sub-side edge 522, thereby improving the connection yield between the second sub-side edge 522 and the isolation structure 300. In one embodiment, as shown in FIGS. 1 and 2, in a direction perpendicular to the thickness direction Z of the display panel, a minimum spacing d between the second short edge 222 and the orthographic projection of the second sublayer 302 on the substrate 100 is greater than or equal to 0.8 micrometer, reducing the impact of the second short edge 222 on the flatness of the second sublayer 302, where the second short edge and the second sublayer are located in the same isolation opening 304. The minimum spacing d between the second short edge 222 and the orthographic projection of the second sublayer 302 on the substrate 100 is greater than or equal to 0.8 micrometer, which may specifically be 0.8 micrometer, 0.9 micrometer, 1 micrometer, 1.1 micrometers, 1.2 micrometers, 1.3 micrometers, 1.5 micrometers, etc., where the second short edge and the second sublayer are located in the same isolation opening 304.

As shown in FIGS. 1 to 4, in some embodiments, the first isolation sub-structure 310 extends in the first direction X, and the second isolation sub-structure 320 extends in the second direction Y. Two oppositely disposed first isolation sub-structures 310 and two oppositely disposed second isolation sub-structures 320 enclose the isolation opening 304. An extension length of the first isolation sub-structures 310 in the first direction X is greater than or equal to an extension length of the second isolation sub-structure 320 in the second direction Y. The first electrode 200 includes two second surfaces disposed opposite to each other in the thickness direction Z of the display panel and a sidewall connected between the two second surfaces, the sidewall including a first sidewall 230 on a side of the first electrode 200 that faces the first isolation sub-structure 310 and a second sidewall 240 on a side of the first electrode that faces the second isolation sub-structure 320. An orthographic projection of the first sidewall 230 on the substrate 100 forms the first edge 210, and the second sidewall 240 includes a first sub-portion 241 and a second sub-portion 242 that are disposed opposite to each other in the first direction X. An orthographic projection of the first sub-portion 241 on the substrate 100 forms the first short edge 221, and an orthographic projection of the second sub-portion 242 on the substrate 100 forms the second short edge 222. The display panel further includes a light-emitting layer disposed on a side of the first electrode layer that faces away from the substrate 100. The light-emitting layer includes light-emitting units 400 disposed in the isolation openings 304. The second electrode layer is disposed on a side of the light-emitting layer that faces away from the substrate 100. Two second isolation sub-structures 320 each include a first sub-segment 321 close to the first sub-portion 241 and a second sub-segment 322 close to the second sub-portion 242, and the second electrode 500 is electrically connected to the second sub-segment 322.

In these embodiments, two first isolation sub-structures 310 are disposed opposite to each other in the second direction Y, and two second isolation sub-structures 320 are disposed opposite to each other in the first direction X. An extension length of the first isolation sub-structure 310 in the first direction X is greater than or equal to an extension length of the second isolation sub-structure 320 in the second direction Y. The sidewall includes the first sidewall 230 on the side of the first electrode 200 that faces the first isolation sub-structure 310 and the second sidewall 240 on the side of the first electrode that faces the second isolation sub-structure 320. Two first sidewalls 230 are disposed opposite to each other in the second direction Y, and two second sidewalls 240 are disposed opposite to each other in the first direction X. Orthographic projections of the two first sidewalls 230 on the substrate 100 form two first edges 210, respectively. The second sidewall 240 includes the first sub-portion 241 and the second sub-portion 242 that are disposed opposite to each other in the first direction X. The orthographic projection of the first sub-portion 241 on the substrate 100 forms the first short edge 221, and the orthographic projection of the second sub-portion 242 on the substrate 100 forms the second short edge 222. The light-emitting layer is disposed on a side of the first electrode layer that faces away from the substrate 100, and the light-emitting layer includes the light-emitting units 400 disposed in the isolation openings 304.

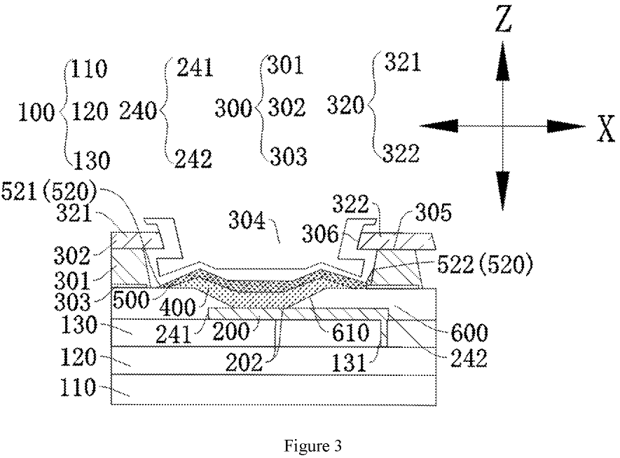

In one embodiment, as shown in FIG. 3, an orthographic projection of the first surface 305 of the second sub-segment 322 on the substrate 100 at least partially overlaps the orthographic projection of the second sub-portion 242 on the substrate 100, which reduces the impact of the second sub-portion 242 on the flatness of part of the second sublayer 302 of the second sub-segment 322 that protrudes from the first surface 305, and increases the flatness of the part of the second sublayer 302 of the second sub-segment 322 that protrudes from the first surface 305.

In one embodiment, the second electrode 500 is electrically connected to the first isolation sub-structure 310 and the second sub-segment 322, and the first electrode 200 extends into the part on a side of the first surface 305 of the first isolation sub-structure 310 that faces the substrate 100 and into the part on a side of the first surface 305 of the second sub-segment 322 that faces the substrate 100. The orthographic projections of the two first sidewalls 230 on the substrate 100 at least partially overlap the orthographic projection of the first surface 305 of the first isolation sub-structure 310 on the substrate 100, and the second electrode 500 extends toward the first isolation sub-structure 310 to be electrically connected to the first isolation sub-structure 310, enabling the first sidewall 230 to have a minor impact on the uniformity of the film layer of the second electrode 500 during manufacturing. The orthographic projection of the second sub-portion 242 on the substrate 100 at least partially overlaps the orthographic projection of the first surface 305 of the second sub-segment 322 on the substrate 100, and the second electrode 500 extends toward the second sub-segment 322 to be electrically connected to the second sub-segment 322, enabling the second sub-portion 242 to have a minor impact on the uniformity of the film layer of the second electrode 500 during manufacturing.

The orthographic projection of the first sub-portion 241 on the substrate 100 is spaced apart from an orthographic projection of the first sub-segment 321 on the substrate 100, which reduces the impact on the manufacturing of the film layer formed on a side of the first sub-portion 241 that faces away from the substrate 100. The second electrode 500 is spaced apart from the first sub-segment 321, which reduces the impact of the first sub-portion 241 on the yield of the second electrode 500 being electrically connected to the isolation structure 300.

As shown in FIG. 3, in some embodiments, the isolation structure 300 further includes a third sublayer 303. The third sublayer 303 is disposed on a side of the first sublayer 301 that faces the substrate 100.

In these embodiments, during lateral etching of the first sublayer 301, the third sublayer 303 may protect the film layer on the side of the substrate 100.

In one embodiment, as shown in FIG. 3, an orthographic projection, on the substrate 100, of a side of the third sublayer 303 of the first sub-segment 321 that faces the first sub-portion 241 is within an orthographic projection of the first surface 305 of the first sub-segment 321 on the substrate 100, and the third sublayer 303 of the first sub-segment 321 is insulated and spaced apart from the second electrode 500.

The functional layer of the light-emitting unit 400 includes a hole inject layer (HIL), a hole transport layer (HTL), an electron inject layer (EIL), and an electron transport layer (ETL). Since the first sub-portion 241 and the first sub-segment 321 are spaced apart from each other in a direction perpendicular to the display panel, forming the light-emitting unit 400 and the second electrode 500 on the side of the first sub-portion 241 that faces away from the substrate 100 may affect the uniformity of the film layers of the light-emitting unit 400 and the second electrode 500, thereby causing electricity leakage. The orthographic projection, on the substrate 100, of the side of the third sublayer 303 of the first sub-segment 321 that faces the first sub-portion 241 is within the orthographic projection of the first surface 305 of the first sub-segment 321 on the substrate 100, which enables the third sublayer 303 to be insulated and spaced apart from the second electrode 500, thereby reducing the risk of electricity leakage.

In one embodiment, the third sublayer 303 of the second sub-segment 322 protrudes toward the isolation opening 304 from the first sublayer 301 and is electrically connected to the second electrode 500.

In one embodiment, the third sublayer 303 of the first isolation sub-structure 310 protrudes toward the isolation opening 304 from the first sublayer 301, and is connected to the second electrode 500.

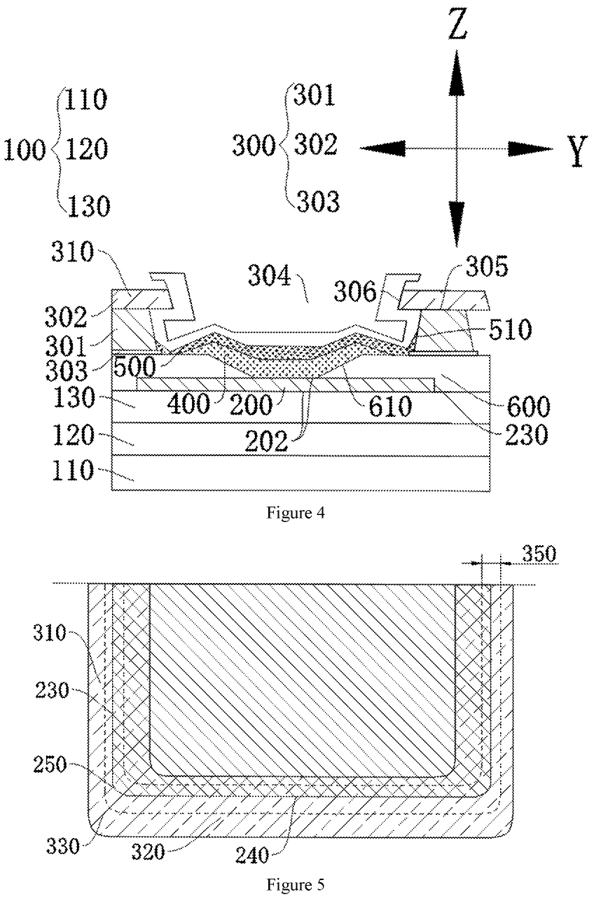

In one embodiment, the material of the third sublayer 303 includes molybdenum. Since oxidation may occur on the surface of the first sublayer 301 during the preparation of the display panel, electrically connecting the third sublayer 303 to the second electrodes 500 facilitates a reduction in the resistivity. In one embodiment, as shown in FIG. 4, the orthographic projection of the first sidewall 230 on the substrate 100 at least partially overlaps the orthographic projection of the first surface 305 of the first isolation sub-structure 310 on the substrate 100, which reduces the impact of the first sidewall 230 on the flatness of the part of the second sublayer 302 of the first isolation sub-structure 310 that protrudes toward the isolation opening 304 from the first surface 305.

In one embodiment, the second sublayer 302 includes a third sidewall 306 on a side that faces the isolation opening 304. In the direction perpendicular to the thickness direction Z of the display panel, a minimum spacing between the second sub-portion 242 and the third sidewall 306 is greater than a minimum spacing between the first sidewall 230 and the third sidewall 306, and part of the first electrode 200 that faces the second sub-portion 242 can be electrically connected to the drive circuit layer 120 through the first via 131.

In one embodiment, as shown in FIG. 4, in the direction perpendicular to the thickness direction Z of the display panel, a minimum spacing between the third sidewall 306 and the first sidewall 230 that are located in the same isolation opening 304 is greater than or equal to 0.8 micrometer, reducing the impact of the first sidewall 230 on the flatness of the second sublayer 302. The minimum spacing between the third sidewall 306 and the first sidewall 230 that are located in the same isolation opening 304 is greater than or equal to 0.8 micrometer, which may specifically be 0.8 micrometer, 0.9 micrometer, 1 micrometer, 1.1 micrometers, 1.2 micrometers, 1.3 micrometers, 1.5 micrometers, etc.

In one embodiment, as shown in FIG. 3, in the direction perpendicular to the thickness direction Z of the display panel, a minimum spacing between the first sub-portion 241 and the third sidewall 306 of the first sub-segment 321 is greater than or equal to 0.8 micrometer, reducing the impact of the first sub-portion 241 on the flatness of the second sublayer 302. The minimum spacing between the first sub-portion 241 and the third sidewall 306 of the first sub-segment 321 is greater than or equal to 0.8 micrometer, which may specifically be 0.8 micrometer, 0.9 micrometer, 1 micrometer, 1.1 micrometers, 1.2 micrometers, 1.3 micrometers, 1.5 micrometers, etc.

As shown in FIG. 5, in some embodiments, the isolation structure 300 includes a first transition segment 330 connected between the first isolation sub-structure 310 and the second isolation sub-structure 320, and the first electrode 200 includes a second transition segment 250 connected between the first sidewall 230 and the second sidewall 240. At least part of an orthographic projection of the second transition segment 250 on the substrate 100 is within an orthographic projection of the first surface 305 of the first transition segment 330 on the substrate 100.

In these embodiments, the at least part of the orthographic projection of the second transition segment 250 on the substrate 100 is within the orthographic projection of the first surface 305 of the first transition segment 330 on the substrate 100, which reduces the impact of the second transition segment 250 on the flatness of part of the second sublayer 302 of the first transition segment 330 that protrudes toward the isolation opening 304 from the first surface 305.

In one embodiment, as shown in FIG. 5, a radius of curvature of the first transition segment 330 is less than a radius of curvature of the second transition segment 250, which prevents the orthographic projection of the second transition segment 250 on the substrate 100 from falling outside the orthographic projection of the first surface 305 of the first transition segment 330 on the substrate 100, thereby improving the flatness of the part of the second sublayer 302 that protrudes toward the isolation opening 304 from the first surface 305.

As shown in FIG. 2, in some embodiments, a size of the second isolation sub-structure 320 in the first direction X is less than a size of the first isolation sub-structure 310 in the second direction Y.

In these embodiments, since the orthographic projection of the first sidewall 230 on the substrate 100 at least partially overlaps the orthographic projection of the first surface 305 of the first isolation sub-structure 310 on the substrate 100, the orthographic projection of the first sub-portion 241 on the substrate 100 is spaced apart from an orthographic projection of the second isolation sub-structure 320 on the substrate 100, and the second isolation sub-structure 320 is not required to cover the first sub-portion 241, the size of the second isolation sub-structure 320 in the first direction X is less affected by the first electrode 200, enabling a reduction in the size of the second isolation sub-structure 320 in the first direction X and an increase in the opening area of the isolation opening 304, thereby improving the display effect of the display panel.

In one embodiment, as shown in FIG. 3, the display panel further includes a pixel definition layer. The pixel definition layer includes a pixel defining portion 600 and a pixel opening 610 enclosed by the pixel defining portion 600. The light-emitting unit 400 is located in the pixel opening 610, and the isolation structure 300 is disposed on a side of the pixel defining portion 600 that faces away from the substrate 100. The pixel defining portion 600 of the pixel definition layer encloses the pixel opening 610 to accommodate the light-emitting unit 400, to realize normal light emission of the light-emitting unit 400. In addition, the pixel defining portion 600 defines an accommodation area of each of light-emitting units 400 to reduce color cast between the light-emitting units 400.

The first electrode 200 includes a metallic material, and the first sidewall 230 and the second sidewall 240 of the first electrode 200 are relatively sharp. The pixel defining portion 600 covering sides of the first sidewall 230 and the second sidewall 240 that face away from the substrate 100 reduces damage to other film layers by the first sidewall 230 and the second sidewall 240. The pixel defining portion 600 is configured to support the isolation structure 300, and the size of the second isolation sub-structure 320 in the first direction X is less than the size of the first isolation sub-structure 310 in the second direction Y. In one embodiment, a size, in the first direction X, of the pixel defining portion 600 on a side of the second isolation sub-structure 320 that faces the substrate 100 is less than a size, in the second direction Y, of the pixel defining portion 600 on a side of the first isolation sub-structure 310 that faces the substrate 100, which facilitates an increase in the opening area of the pixel opening 610, thereby improving the display effect of the display panel.

In the first aspect, the present application further provides a display panel. The display panel includes: a substrate 100, a first electrode layer, an isolation structure 300, and a second electrode layer, where the first electrode layer is disposed on a side of the substrate 100, and the first electrode layer includes a plurality of first electrodes 200 spaced apart from each other; the isolation structure 300 is disposed on a side of the substrate 100, and the isolation structure 300 encloses isolation openings 304, an orthographic projection of the isolation opening 304 on the substrate 100 at least partially overlapping an orthographic projection of the first electrode 200 on the substrate 100, where the isolation structure 300 includes a first sublayer 301 and a second sublayer 302 that are stacked in a direction away from the substrate 100, an orthographic projection of the first sublayer 301 on the substrate 100 being within an orthographic projection of the second sublayer 302 on the substrate 100, and the first sublayer 301 having a first surface 305 on a side that faces the second sublayer 302; and the orthographic projection of the first electrode 200 on the substrate 100 includes a first edge 210 extending in a first direction X and a second edge 220 extending in a second direction Y, where an extension length of the first edge 210 in the first direction X is greater than or equal to an extension length of the second edge 220 in the second direction Y, the first direction X intersecting the second direction Y; and the second electrode layer is disposed on a side of the first electrode layer that faces away from the substrate 100, and the second electrode layer includes second electrodes 500 located in the isolation openings 304, where the isolation structure 300 enclosing the same isolation opening 304 includes a first isolation sub-structure 310 and a second isolation sub-structure 320, where the first isolation sub-structure 310 is disposed in contact with the second electrode 500, and an orthographic projection of the first surface 305 of the first isolation sub-structure 310 on the substrate 100 overlaps the first edge 210; and at least part of an orthographic projection of the second isolation sub-structure 320 on the substrate 100 is spaced apart from the second edge 220.

In this embodiment, two first edges 210 are disposed opposite to each other in the second direction Y, and two second edges 220 are disposed opposite to each other in the first direction X. The at least part of the orthographic projection of the second isolation sub-structure 320 on the substrate 100 is spaced apart from the second edge 220, which reduces the parasitic capacitance generated due to part on a side of the first electrode 200 that faces the second edge 220 directly facing the isolation structure 300. The display panel may further include the second electrode 500. The second electrode 500 is configured to be electrically connected to the isolation structure 300. The first edge 210 at least partially overlaps the orthographic projection of the first surface 305 of the first isolation sub-structure 310 on the substrate 100, which reduces the impact of a sidewall on a side of the first electrode 200 that faces the first edge 210 on the formation of the second electrode 500. In addition, the extension length of the first edge 210 in the first direction X is greater than or equal to the extension length of the second edge 220 in the second direction Y, which facilitates an increase in the area of contact between the second electrode 500 and the isolation structure 300 and a reduction in the resistance of the second electrode 500, thereby improving the process performance of the display panel.

In some embodiments, the first electrode 200, the second electrode 500, and the isolation structure 300 are disposed as described above, which will not be repeated herein.

In the first aspect, the present application further provides a display panel. The display panel includes: a substrate 100, a first electrode layer, and an isolation structure 300, where the first electrode layer is disposed on a side of the substrate 100, and the first electrode layer includes a plurality of first electrodes 200 spaced apart each other; the isolation structure 300 is disposed on a side of the substrate 100, and the isolation structure 300 encloses isolation openings 304, an orthographic projection of the isolation opening 304 on the substrate 100 at least partially overlapping an orthographic projection of the first electrode 200 on the substrate 100, where the isolation structure 300 includes a first sublayer 301 and a second sublayer 302 that are stacked in a direction away from the substrate 100, an orthographic projection of the first sublayer 301 on the substrate 100 being within an orthographic projection of the second sublayer 302 on the substrate 100, and the first sublayer 301 having a first surface 305 on a side that faces the second sublayer 302; the isolation structure 300 includes a first isolation sub-structure 310, a second isolation sub-structure 320, and a first transition segment 330 connected between the first isolation sub-structure 310 and the second isolation sub-structure 320; the first electrode 200 includes two second surfaces disposed opposite to each other in the thickness direction Z of the display panel and a sidewall connected between the two second surfaces, the sidewall including a first sidewall 230 on a side of the first electrode 200 that faces the first isolation sub-structure 310 and a second sidewall 240 on a side of the first electrode that faces the second isolation sub-structure 320; and the first electrode 200 further includes a second transition segment 250 connected between the first sidewall 230 and the second sidewall 240, where at least part of an orthographic projection of the second transition segment 250 on the substrate 100 is within an orthographic projection of the first surface 305 of the first transition segment 330 on the substrate 100.

In this embodiment, the at least part of the orthographic projection of the second transition segment 250 on the substrate 100 is within the orthographic projection of the first surface 305 of the first transition segment 330 on the substrate 100, which from reduces the impact of the second transition segment 250 on the flatness of part of the second sublayer 302 of the first transition segment 330 that protrudes toward the isolation opening 304 the first surface 305.

In one embodiment, a radius of curvature of the first transition segment 330 is less than a radius of curvature of the second transition segment 250, which prevents the orthographic projection of the second transition segment 250 on the substrate 100 from falling outside the orthographic projection of the first surface 305 of the first transition segment 330 on the substrate 100, thereby improving the flatness of the part of the second sublayer 302 that protrudes toward the isolation opening 304 from the first surface 305.

An embodiment of a second aspect of the present application further provides a display apparatus, including a display panel according to any one of the above-described embodiments of the first aspect. Since the display apparatus according to the embodiment of the second aspect of the present application includes the display panel according to any one of the above-described embodiments of the first aspect, the display apparatus according to the embodiment of the second aspect of the present application has the beneficial effects of the display panel according to any one of the above-described embodiments of the first aspect, which will not be repeated herein.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

Although the present application has been described with reference to some embodiments, various modifications can be made thereto, and components therein can be replaced with equivalents without departing from the scope of the present application. In particular, the embodiments can be combined in any manner, provided that there is no structural conflict. The present application is not limited to the embodiments disclosed herein but includes all the embodiments that fall within the scope of the claims.

1. A display panel, comprising:
a substrate;
a first electrode layer disposed on a side of the substrate, the first electrode layer comprising a plurality of first electrodes spaced apart from each other;
an isolation structure disposed on a side of the substrate, the isolation structure enclosing a plurality of isolation openings, an orthographic projection of the isolation opening on the substrate at least partially overlapping an orthographic projection of the first electrode on the substrate, wherein the isolation structure comprises a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer; and
a second electrode layer disposed on a side of the first electrode layer that faces away from the substrate, the second electrode layer comprising a plurality of second electrodes located in the isolation openings,
wherein the isolation structure enclosing the same isolation opening comprises a first isolation sub-structure and a second isolation sub-structure, wherein the first isolation sub-structure is disposed in contact with the second electrode, and an orthographic projection of the first surface of the first isolation sub-structure on the substrate overlaps one part of an edge of the orthographic projection of the first electrode on the substrate; and an area of contact between the second isolation sub-structure and the second electrode is less than an area of contact between the first isolation sub-structure and the second electrode, and at least part of an orthographic projection of the second sublayer of the second isolation sub-structure on the substrate is spaced apart from another part of the edge of the orthographic projection of the first electrode on the substrate.

2. The display panel according to claim 1, wherein the orthographic projection of the first electrode on the substrate comprises a first edge extending in a first direction and a second edge extending in a second direction, wherein an extension length of the first edge in the first direction is greater than an extension length of the second edge in the second direction, the first edge at least partially overlaps the orthographic projection of the first surface of the first isolation sub-structure on the substrate, and at least part of the second edge is spaced apart from the orthographic projection of the second sublayer of the second isolation sub-structure on the substrate, the first direction intersecting the second direction.

3. The display panel according to claim 1, wherein the second electrode comprises a first side edge extending in a first direction and a second side edge extending in a second direction, wherein an extension length of the first side edge in the first direction is greater than an extension length of the second side edge in the second direction, the first side edge is connected to the first isolation sub-structure, and an area of contact between the second side edge and the second isolation sub-structure is less than an area of contact between the first isolation sub-structure and the first side edge; and
at least part of the second side edge is spaced apart from the second isolation sub-structure.

4. The display panel according to claim 2, wherein two second edges are disposed opposite to each other in the first direction, with one of the two second edges being a first short edge, and the other of the two second edges being a second short edge; and the substrate comprises a base, a drive circuit layer, and an insulating layer that are disposed sequentially, the first electrode and the isolation structure being disposed on a side of the insulating layer that faces away from the base, and the insulating layer being provided with a first via through which the first electrode is electrically connected to the drive circuit layer, wherein an orthographic projection of the first via on the base is on a side where the second short edge is located, the first short edge is spaced apart from an orthographic projection of the second sublayer of the second isolation sub-structure on the base, and the second short edge at least partially overlaps an orthographic projection of the first surface of the second isolation sub-structure on the base.

5. The display panel according to claim 4, wherein two second side edges are disposed opposite to each other in the first direction, and the two second side edges comprise a first sub-side edge away from a side where the first via is located and a second sub-side edge close to the side where the first via is located, wherein the first sub-side edge is spaced apart from the isolation structure, and the second sub-side edge is connected to the isolation structure; and
in a direction perpendicular to a thickness direction of the display panel, a minimum spacing between the second short edge and the orthographic projection of the second sublayer on the substrate is greater than or equal to 0.8 micrometer, wherein the second short edge and the second sublayer are located in the same isolation opening.

6. The display panel according to claim 4, wherein the first isolation sub-structure extends in the first direction, the second isolation sub-structure extends in the second direction, and two oppositely disposed first isolation sub-structures and two oppositely disposed second isolation sub-structures enclose the isolation opening, wherein an extension length of the first isolation sub-structure in the first direction is greater than or equal to an extension length of the second isolation sub-structure in the second direction;
the first electrode comprises two second surfaces disposed opposite to each other in a thickness direction of the display panel and a sidewall connected between the two second surfaces, the sidewall comprising a first sidewall on a side of the first electrode that faces the first isolation sub-structure and a second sidewall on a side of the first electrode that faces the second isolation sub-structure, wherein an orthographic projection of the first sidewall on the substrate forms the first edge, and the second sidewall comprises a first sub-portion and a second sub-portion that are disposed opposite to each other in the first direction, an orthographic projection of the first sub-portion on the substrate forming the first short edge, and an orthographic projection of the second sub-portion on the substrate forming the second short edge; and
the display panel further comprises a light-emitting layer disposed on a side of the first electrode layer that faces away from the substrate, the light-emitting layer comprising light-emitting units disposed in the isolation openings, wherein the second electrode layer is disposed on a side of the light-emitting layer that faces away from the substrate, two second isolation sub-structures each comprise a first sub-segment close to the first sub-portion and a second sub-segment close to the second sub-portion, the second electrode being electrically connected to the second sub-segment, and the second electrode being spaced apart from the first sub-segment.

7. The display panel according to claim 6, wherein an orthographic projection of the first surface of the second sub-segment on the substrate at least partially overlaps the orthographic projection of the second sub-portion on the substrate; and
the second electrode is electrically connected to the first isolation sub-structure and the second sub-segment.

8. The display panel according to claim 6, wherein the isolation structure further comprises a third sublayer disposed on a side of the first sublayer that faces the substrate,
wherein an orthographic projection, on the substrate, of a side of the third sublayer of the first sub-segment that faces the first sub-portion is within an orthographic projection of the first surface of the first sub-segment on the substrate, and the third sublayer of the first sub-segment is insulated and spaced apart from the second electrode.

9. The display panel according to claim 6, wherein the third sublayer of the second sub-segment protrudes toward the isolation opening from the first sublayer, and is electrically connected to the second electrode; and
the third sublayer of the first isolation sub-structure protrudes toward the isolation opening from the first sublayer, and is connected to the second electrode.

10. The display panel according to claim 4, wherein the second sublayer comprises a third sidewall on a side that faces the isolation opening, and in a direction perpendicular to a thickness direction of the display panel, a minimum spacing between the second sub-portion and the third sidewall is greater than a minimum spacing between the first sidewall and the third sidewall.

11. The display panel according to claim 10, wherein in the direction perpendicular to the thickness direction of the display panel, a minimum spacing between the third sidewall and the first sidewall that are located in the same isolation opening is greater than or equal to 0.8 micrometer; and
in the direction perpendicular to the thickness direction of the display panel, a minimum spacing between the first sub-portion and the third sidewall of the first sub-segment is greater than or equal to 0.8 micrometer.

12. The display panel according to claim 6, wherein the isolation structure comprises a first transition segment connected between the first isolation sub-structure and the second isolation sub-structure, and the first electrode comprises a second transition segment connected between the first sidewall and the second sidewall, wherein at least part of an orthographic projection of the second transition segment on the substrate is within an orthographic projection of the first surface of the first transition segment on the substrate.

13. The display panel according to claim 12, wherein a radius of curvature of the first transition segment is less than a radius of curvature of the second transition segment.

14. The display panel according to claim 4, wherein a size of the second isolation sub-structure in the first direction is less than a size of the first isolation sub-structure in the second direction.

15. The display panel according to claim 1, further comprising a pixel definition layer, the pixel definition layer comprising a pixel defining portion and a pixel opening enclosed by the pixel defining portion, wherein the light-emitting unit is located in the pixel opening, and the isolation structure is disposed on a side of the pixel defining portion that faces away from the substrate; and
a size, in the first direction, of the pixel defining portion on a side of the second isolation sub-structure that faces the substrate is less than a size, in the first direction, of the pixel defining portion on a side of the first isolation sub-structure that faces the substrate.

16. A display panel, comprising:
a substrate;
a first electrode layer disposed on a side of the substrate, the first electrode layer comprising a plurality of first electrodes spaced apart from each other;
an isolation structure disposed on a side of the substrate, the isolation structure enclosing a plurality of isolation openings, an orthographic projection of the isolation opening on the substrate at least partially overlapping an orthographic projection of the first electrode on the substrate, wherein the isolation structure comprises a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer; and
the orthographic projection of the first electrode on the substrate comprises a first edge extending in a first direction and a second edge extending in a second direction, wherein an extension length of the first edge in the first direction is greater than an extension length of the second edge in the second direction, the first direction intersecting the second direction; and
a second electrode layer disposed on a side of the first electrode layer that faces away from the substrate, the second electrode layer comprising a plurality of second electrodes located in the isolation openings,
wherein the isolation structure enclosing the same isolation opening comprises a first isolation sub-structure and a second isolation sub-structure, wherein the first isolation sub-structure is disposed in contact with the second electrode, and an orthographic projection of the first surface of the first isolation sub-structure on the substrate overlaps the first edge; and at least part of an orthographic projection of the second isolation sub-structure on the substrate is spaced apart from the second edge.

17. The display panel according to claim 16, wherein the second electrode comprises a first side edge extending in the first direction and a second side edge extending in the second direction, the first side edge being connected to the first isolation sub-structure, and at least part of the second side edge being spaced apart from the second isolation sub-structure.

18. A display panel, comprising:
a substrate;
a first electrode layer disposed on a side of the substrate, the first electrode layer comprising a plurality of first electrodes spaced apart from each other; and
an isolation structure disposed on a side of the substrate, the isolation structure enclosing isolation openings, an orthographic projection of the isolation opening on the substrate at least partially overlapping an orthographic projection of the first electrode on the substrate, wherein the isolation structure comprises a first sublayer and a second sublayer that are stacked in a direction away from the substrate, an orthographic projection of the first sublayer on the substrate being within an orthographic projection of the second sublayer on the substrate, and the first sublayer having a first surface on a side that faces the second sublayer;
the isolation structure comprises a first isolation sub-structure, a second isolation sub-structure, and a first transition segment connected between the first isolation sub-structure and the second isolation sub-structure; the first electrode comprises two second surfaces disposed opposite to each other in a thickness direction of the display panel and a sidewall connected between the two second surfaces, the sidewall comprising a first sidewall on a side of the first electrode that faces the first isolation sub-structure and a second sidewall on a side of the first electrode that faces the second isolation sub-structure; and the first electrode further comprises a second transition segment connected between the first sidewall and the second sidewall,
wherein at least part of an orthographic projection of the second transition segment on the substrate is within an orthographic projection of the first surface of the first transition segment on the substrate.

19. The display panel according to claim 18, wherein a radius of curvature of the first transition segment is less than a radius of curvature of the second transition segment.

20. A display apparatus, comprising:
a display panel according to claim 1.
